(19) United States
(12) Patent Application Publication
(10) Pub. No.: US 2009/0015268 A1
(43) Pub. Date: Jan. 15, 2009

(54) DEVICE AND METHOD FOR COMPENSATING A CAPACITIVE SENSOR MEASUREMENT FOR VARIATIONS CAUSED BY ENVIRONMENTAL CONDITIONS IN A SEMICONDUCTOR PROCESSING ENVIRONMENT

(76) Inventors: DelRae H. Gardner, Tualatin, OR (US); Andy K. Lim, Tigard, OR (US)

Correspondence Address: WESTMAN CHAMPLIN & KELLY, P.A., SUITE 1400, 900 SECOND AVENUE SOUTH, MINNEAPOLIS, MN, 55402-3244, US

(21) Appl. No.: 12/169,737

(22) Filed: Jul. 9, 2008

Related U.S. Application Data
(60) Provisional application No. 60/959,436, filed on Jul. 13, 2007.

(51) Int. Cl. G01R 27/26

(52) U.S. Cl. 324/662

(57) ABSTRACT

A method of sensing proximity to a showerhead in a semiconductor-processing system is provided. The method includes measuring a parameter that varies with proximity to the showerhead, as well as with at least one external factor. The method also includes measuring a parameter that does not vary with proximity to the showerhead, but does vary with the at least one factor. A compensated proximity output is calculated based upon the measured parameters and is provided as an output.

### CROSS-REFERENCE TO RELATED APPLICATION

The present application is based on and claims the benefit of U.S. provisional patent application Ser. No. 60/959,436, filed Jul. 13, 2007, the content of which is hereby incorporated by reference in its entirety.

### COPYRIGHT RESERVATION

A portion of the disclosure of this patent document contains material which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### BACKGROUND

Semiconductor wafer processing is a precise and exacting science with which various wafers and/or substrates are processed to become integrated circuits, LCD flat panel displays, and other such electronic devices. The current state of the art in semiconductor processing has pushed modern lithography to new limits with current commercial applications being run at the 45-nanometer scale. Accordingly, modern processing of semiconductors demands tighter and tighter process controls of the processing equipment.

Often a semiconductor processing deposition or etch processing chamber utilizes a device known as a “showerhead” to introduce a reactive gas to the substrate. The device is termed a “showerhead” in that it vaguely resembles a showerhead being generally circular, and having a number of apertures through which the reactive gas is expelled onto the substrate.

In the field of semiconductor manufacturing, precise and accurate measurement and adjustment of the distance between the showerhead and a substrate-supporting pedestal in such a deposition or etch processing chamber are needed in order to effectively control the process. If the distance of the gap between the showerhead and the substrate-supporting pedestal are not accurately known, the rate at which the deposition or etching occurs may vary undesirably from a nominal rate. Further, if the pedestal is inclined, to some extent, relative to the showerhead, the rate at which one portion of the substrate is processed via the deposition or etching process will be different than the rate at which other portions are processed. Accordingly, it is imperative in semiconductor processing to accurately determine both the distance of the gap, and any inclination of the substrate-supporting pedestal relative to the showerhead. As set forth herein, “proximity” is intended to mean the distance of the gap, any inclination of the substrate-supporting pedestal relative to the showerhead, or any combination thereof.

Recently, a semiconductor processing system with an integrated showerhead distance measuring device was disclosed in the U.S. patent application Ser. No. 12/055,744, filed Mar. 26, 2008. The system disclosed therein allows for precise measurements of the gap between the pedestal and the showerhead, and/or inclination of the showerhead or pedestal with respect to the other.

Generally, capacitance-based sensors are based on the existence and change of capacitance in a capacitor that includes the object being measured. For example, in the case of the capacitance-based measurement disclosed in the United States Patent Application listed above, there is a capacitance between the sensor surface and the showerhead, or a capacitance between the showerhead and an associated metallic object, and this capacitance changes inversely with the separation between the showerhead and the object. The separation can be determined by knowing the relationship of separation to capacitance, or to a function of the circuit that depends on the capacitance, such as frequency of oscillation.

One difficulty with such capacitance-based measurements is that the capacitance can also be affected by external factor (influences that are not directly related to the proximity of the showerhead. Generally, these external factors will include environmental conditions such as, for example, relative humidity or temperature, as well as less understood factors that are thought to be due to changes in the circuit that occur with age. In the measurement function, these external factors generally cannot be separated from measurement capacitance due to the object being sensed. Thus, environmentally or age-induced capacitance changes or indeed any change that is not due to change of the object being measured, may cause an error in the measurement of the gap and/or parallelism.

### SUMMARY

A method of sensing proximity to a showerhead in a semiconductor-processing system is provided. The method includes measuring a parameter that varies with proximity to the showerhead, as well as with at least one external factor. The method also includes measuring a parameter that does not vary with proximity to the showerhead, but does vary with the at least one factor. A compensated proximity output is calculated based upon the measured parameters and is provided as an output.

### BRIEF DESCRIPTION OF THE DRAWINGS

FIG. 1 is a diagrammatic view of a semiconductor-processing chamber with which embodiments of the present invention are particularly applicable.

FIG. 2 is a more detailed diagrammatic view of a semiconductor-processing chamber with which embodiments of the present invention are particularly applicable.

FIG. 3 is a diagrammatic view of a semiconductor-processing chamber in accordance with an embodiment of the present invention.

FIG. 4 is a diagrammatic view of a substrate-like sensor in accordance with an embodiment of the present invention.

FIG. 5 is a flow diagram of a method of compensating a capacitive sensor measurement relative to proximity between a pedestal and a showerhead in a semiconductor processing environment in accordance with an embodiment of the present invention.

### DETAILED DESCRIPTION OF ILLUSTRATIVE EMBODIMENTS

Embodiments of the present invention generally employ one or more conductive regions on a showerhead and/or substrate-supporting pedestal to form a capacitor, the capacitance of which varies with the distance between the two conductive surfaces. Additionally, embodiments of the present invention generally include a pair of conductors forming a reference capacitor that is not sensitive to changes in distance between the pedestal and the showerhead, but is sensitive to preferably all other variables.

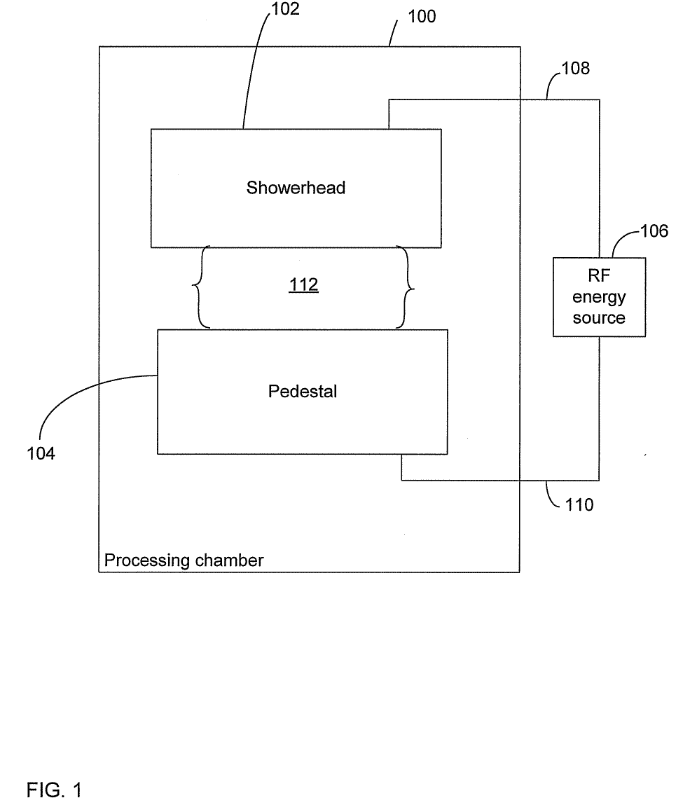

FIG. 1 is a diagrammatic view of a semiconductor-processing chamber with which embodiments of the present invention are particularly applicable. Processing chamber 100 includes a showerhead 102 disposed above, or at least spaced apart from pedestal 104. Typically, the wafer or substrate will rest upon pedestal 104 while it is processed in processing chamber 100. As illustrated in FIG. 1, a source 106 of radio frequency energy is electrically coupled to showerhead 102 and pedestal 104 via respective conductors 108 and 110. By providing radio frequency energy to showerhead 102 and pedestal 104, reactive gas introduced from showerhead 102 can form plasma in region 112 between pedestal 104 and showerhead 102 in order to process a wafer or semiconductor substrate.

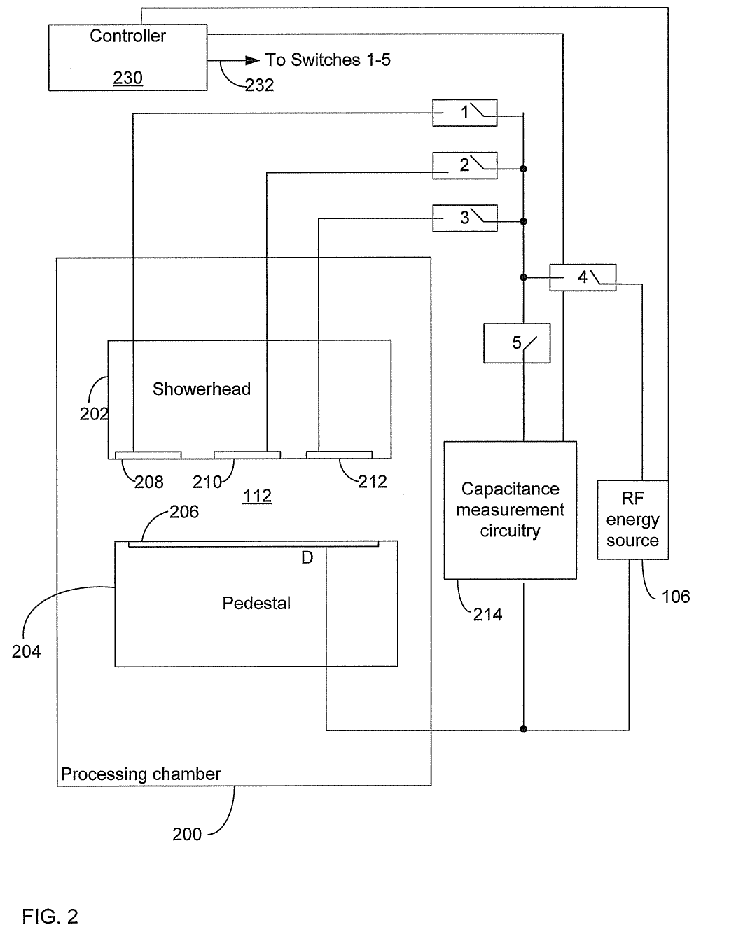

FIG. 2 is a more detailed diagrammatic view of a semiconductor-processing chamber with which embodiments of the present invention are particularly applicable. Chamber 200 bears some similarities to chamber 100, and like components are numbered similarly. Processing chamber 200 includes pedestal 204 and showerhead 202, both of which are preferably non-conductive. Pedestal 204 includes a conductive electronic layer or plate 206 that is arranged on a surface of pedestal 204 that faces showerhead 202. Similarly, showerhead 202 preferably includes a plurality of electronic layers or conductive surfaces 208, 210 and 212. Each of electrodes 208, 210 and 212 form a respective capacitor with plate 206. The capacitance of each respective capacitor is related to the distance between each respective capacitive plate on showerhead 202, and plate 206 on pedestal 204.

As illustrated in FIG. 2, the system includes not only RF energy source 106, but also a capacitance measurement circuit 214 that can be alternately coupled to the plates 208, 210 and 212 by virtue of various switches. Circuitry for measuring capacitance is well known. Such circuitry may include known analog-to-digital converters as well as suitable excitation and/or driver circuitry. As illustrated in FIG. 2, each of RF energy source 106 and capacitance measurement circuit 214 is coupled to a respective switch 4, 5 such that energy source 106, and capacitance measurement circuit 214 are not coupled to capacitive plates at the same time. Thus, during normal processing, switch 5 is open and switch 4 is closed thereby coupling RF energy source 106 to the processing chamber. Further, during normal processing, all of switches 1, 2 and 3 are closed such that RF energy source 106 is coupled to all of plates 208, 210 and 212, simultaneously. During gap measurement, switch 4 is opened and switch 5 is closed. Further, only one of switches 1, 2 and 3 is closed at a time with the other switches being opened. This allows the capacitance between a particular capacitance plate such as 208, 210, 212, and plate 206 to be measured to determine the distance between showerhead 202 and the pedestal 204 at the location of the respective capacitive plate. As further illustrated in FIG. 2, a controller, such as controller 230, is preferably coupled to switches 1-5, as illustrated at reference numeral 232 and also to RF energy source 106 and capacitance measurement circuit 214. In this manner, controller 230 can suitably actuate the various switches 1-5, and engage RF energy source 106 or capacitance measurement circuit 214 when appropriate. Further, capacitance measurement circuit 214 can report the various capacitance measurements, for example by digital communication, to controller 230.

The description above with respect to FIGS. 1 and 2 describes substantially the system set forth in U.S. patent application Ser. No. 12/055,744. Embodiments of the present invention generally provide an improvement upon that system. Specifically, a circuit is made to include a reference capacitor that is preferably formed on the surface of the printed circuit board of the sensor in the same way that the sensing capacitors are formed. The reference capacitor is preferably subject to the same environmental conditions and changes as the sensing capacitors, and thus experiences the same changes of capacitance which are not due to proximity to the object being sensed. However, the reference capacitor is placed where it does not experience any change in capacitance due to the change in distance to the object being sensed.

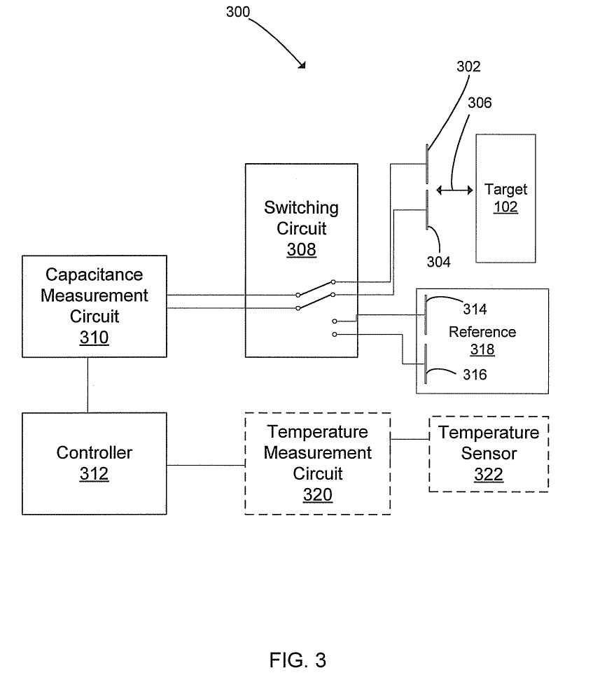

FIG. 3 is a diagrammatic view of a semiconductor processing environment in accordance with an embodiment of the present invention. System 300 bears some similarities to systems described with respect to FIGS. 1 and 2, and like components are numbered similarly. System 300 includes a pair of capacitive plates 302, 304 that create a capacitor with target object, or showerhead 102, the capacitance of which varies with the distance 306 between plates 302, 304 and target object 102. Additionally, as it is set forth above, the capacitance also varies with a number of other variables including temperature and/or relative humidity, as well as other less understood causes. Each of capacitive plates 302, 304 are coupled to switching circuit 308, which selectively couples plates 302, 304 to capacitance measurement circuit 310. Capacitance measurement circuit 310 can be any suitable circuitry for measuring, or otherwise observing, a capacitance. Additionally, capacitance measurement circuit 310 can be identical to capacitance measurement circuitry 214 described above with respect to FIG. 2. Capacitance measurement circuit 310 and switching circuit 308 are coupled to controller 312 such that controller 312 can selectively engage switching circuit 308 to couple capacitance measurement circuit 310 to plates 302, 304 or to reference plates 314, 316 in reference capacitor 318. Additionally, controller 312 receives information, preferably digital information, from capacitance measurement circuit 310 regarding the capacitance of the plates to which it is coupled through switching circuit 308. Controller 312 may be any suitable controller, including controller 230, described with respect to FIG. 2. Additionally, while the embodiment illustrated in FIG. 3 illustrates a single measurement capacitor comprised of plates 302, 304, switching circuit 308 can include a number of additional contacts, such as those set forth with respect to FIG. 2, such that various additional capacitive plates, including capacitive plates disposed on, or embedded within, target object 102 can be utilized. In this manner, various locations and inclinations can be sensed.

Reference capacitor 318 preferably is disposed within the same sensor housing as plates 302 and 304. More specifically, it is preferred that reference capacitor 318 be formed on the surface of the printed circuit board that comprises the various electrical components of the sensor. Such electrical components include controller 312, measurement circuit 310, and switching circuit 308. In this way, reference capacitor 318 will experience the same changes of capacitance which are not due to proximity of target object 102. For example, reference capacitor 318 will be subject to the same temperature and relative humidity as capacitive plates 302 and 304. Controller 312 will cause switching circuit 308 to operably couple plates 314 and 316 to capacitance measurement circuit 310. Capacitance measurement circuit 310 will then measure the capacitance of reference capacitor 318, and provide an indication of that capacitance to controller 312. Controller 312 can then use the capacitance of the reference capacitor to compensate, or otherwise remove, effects on the capacitance measured from plates 302, 304 that are not due to gap 306. Reference capacitor 318 need not be the same size, physically or electrically, as sensing capacitor plates 302, 304. This is because reference capacitance change can be scaled before compensation. For example, if reference capacitance has a nominal value that is half that of the sensing capacitor, then the change measured on the reference capacitor would be doubled before compensating for the changes in the sensing capacitor.

While the arrangement illustrated in FIG. 3 specifically shows a switching circuit 308 that is used to selectively couple either sensing plate 302, 304 to measurement circuit 310, or reference plates 314, 316 to measurement circuit 310, other arrangements can be used in accordance with embodiments of the present invention. Specifically, if two capacitance measurement circuits were employed, one such measurement circuit could be coupled directly to plates 302, 304 while a second could be coupled to reference capacitor 318, thereby obviating the need for switching circuit 308. Further still, embodiments of the present invention include electrical connections, arrangements or circuits that automatically cause the capacitance of reference capacitor 318 to be subtracted from, or otherwise compensated from, capacitance measured across plates 302, 304. Additionally, while it may be preferable to measure the reference capacitance each and every time a sensing capacitance is measured, that need not be the case. Specifically, a reference capacitance can be measured periodically, based on time, relative change of the reference capacitance, an interval of sensing capacitance measurements, or any other suitable interval.

FIG. 3 also illustrates the utilization of an optional temperature sensor 322. Temperature sensor 322 is preferably coupled to controller 312 through temperature measurement circuitry 320, which can be any suitable circuitry for measuring an electrical property of temperature sensor 322. Temperature sensor 322 can be any suitable temperature sensing device, such as a Resistance Temperature Device (RTD), a thermocouple, a thermistor. Accordingly, circuitry 320 is able to measure an electrical characteristic (such as voltage in the case of a thermocouple) and provide an indication of the measured parameter to controller 312. Controller 312 preferably uses the measured temperature value to compensate for physical changes in the proximity sensor that are due to thermally-induced dimensional changes.

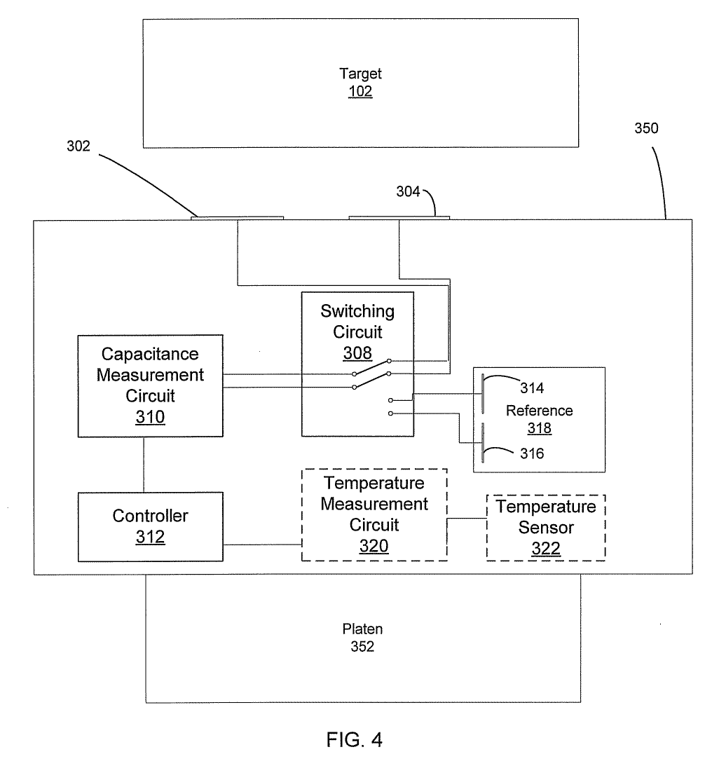

FIG. 4 is a diagrammatic view of a substrate-like sensor in accordance with an embodiment of the present invention. Sensor 350 includes many of the same components described above, and like components are numbered similarly. While sensor 350 is illustrated in block diagram form, the physical size and shape of sensor 350 are preferably selected to approximate a substrate that is processed by the semiconductor processing system, such as a semiconductor wafer or LCD flat panel. Thus, the block diagram form is provided for ease of illustration and should not be considered to indicate the physical characteristics of sensor 350. Sensor 350 rests upon platen 352 and includes a plurality of capacitive plates 302, 304 that form a capacitor having a capacitance that varies with the distance to target 102. Additionally, within the housing of sensor 352, reference capacitive plates 314 and 316 are also coupled to switching circuit 308. This allows controller 312 to selectably measure capacitive effects that are not attributed to the distance to target 102. These effects are then removed, either electrically, or in software, and a compensated gap measurement (gap distance, shape, or both) is provided.

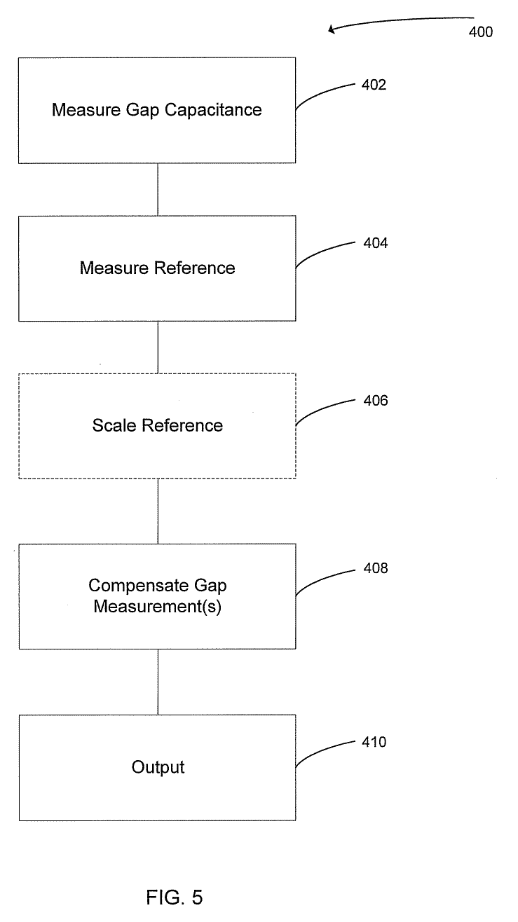

FIG. 5 is a flow diagram of a method of compensating a capacitive sensor measurement relative to a gap between a pedestal and a showerhead in a semiconductor processing environment in accordance with an embodiment of the present invention. Method 400 begins at block 402 where at least one capacitance relative to a gap between a showerhead and a pedestal, or a sensor resting upon the pedestal, is measured. Next, at block 404, a reference capacitance is measured. As set forth above, the reference capacitance is preferably that of a capacitor that is constructed similarly to the sensing capacitor, but is not configured to have a capacitance that varies with the distance to the showerhead. Next, at block 406, the reference capacitance is optionally scaled. If the reference capacitor is configured to have the exact nominal capacitance of the sensing capacitor, then the scaling step 406 may be omitted. Next, at block 408, the capacitance measured with respect to the gap is compensated, or otherwise adjusted, based upon the measured reference capacitance. This compensation function can include any suitable mathematical function including:

C=(c−(k*)(Cᵣ−Cᵣ₀)));

where
C=resulting compensated capacitance;
c=uncompensated capacitance being read;
Cᵣ=Reference capacitance being read;
Cᵣ₀=Reference capacitance at time t₀;
k=scale factor for capacitance.
   For embodiments that employ the optional temperature sensor, the function can be as follows:

C=(c−(k*(Cᵣ−Cᵣ₀)))−h(T−T₀);

where:
h=scale factor for temperature;
T=current temperature being read;
T₀=temperature at time t₀.

In a preferred implementation the compensation calculation is done in the following manner. At a calibration time, the gap capacitance is measured for a set of known gaps and is recorded along with the associated gaps. This results in a table of gaps versus measured capacitances. To measure an unknown gap, the capacitance is measured and compared to the table. The gap can be determined from the table either by finding the nearest gap, or by interpolation. Also at calibration time the reference capacitance is measured and recorded.

The gap capacitance C is known to be the sum of the capacitance due to the gap Cg, which changes with gap changes, plus other parasitic capacitance Cp1 which does not change with gap, but which changes with other factors such as ambient condition. In equation form this is C=Cg+Cp1. The reference capacitance Cᵣ is known to be the sum the reference capacitor Cr, which does not change, plus other parasitic capacitance Cp2 which changes with factors such as ambient condition, but not with gap. In equation form Cᵣ=Cr+Cp2.

At a later time, when a gap measurement is to be made, ambient conditions may have changed, causing a change to both the parasitic capacitance associated with the gap capacitor, and the parasitic capacitance of the reference capacitor. The changed parasitic capacitances are designated Cp1′ and Cp2′. The gap capacitance is now C′=Cg+Cp1′. The reference capacitance is Cᵣ′=Cr+Cp2′. Any change in Cᵣ is due to a change in parasitic capacitance, so Cᵣ−Cᵣ′=Cp2−Cp2′. Any change in parasitic capacitance applies equally to Cp1 and Cp2, with a possible scaling factor k, which may be determined from the relative sizes of the gap capacitor and the reference capacitor, or may be determined empirically, and in any event is known a priori. So Cp1′=Cp1+k(Cp2−Cp2′). Substituting this into the equation for C′ we have C′=Cg+Cp1+k(Cp2−Cp2′). Since k(Cp2−Cp2′) is known, it can be subtracted from the measured value of C′, or C′−k(Cp2−Cp2′)=Cg+Cp1=C. This effectively transforms C′ into C. In short, C′ is measured, Cᵣ′ is measured, and the scaled difference between Cr and Cr′ is subtracted from C′ to arrive at C. C is then used to find the gap from the table that was recorded at calibration time. Next, at block 410, the gap is output. This output can be in the form of an output to a machine that is able to automatically adjust gap and/or inclination, or can simply be an output that is displayed to a user through a suitable display device.

Although the present invention has been described with reference to preferred embodiments, workers skilled in the art will recognize that changes may be made in form and detail without departing from the spirit and scope of the invention.

What is claimed is:

1. A method of sensing proximity to a showerhead in a semiconductor-processing system, the method comprising:
providing a first sensing capacitive plate that is operably supported by a substrate support pedestal;
providing a second sensing capacitive plate that forms a sensing capacitor with the first sensing capacitive plate, wherein the sensing capacitor has a capacitance that varies with distance between the substrate support pedestal and the showerhead and also varies with at least one external factor;
providing first and second reference capacitive plates to form a reference capacitor having a reference capacitance that does not vary with distance between the substrate support pedestal and the showerhead, but does vary with the at least one external factor;
measuring the capacitance of the sensing capacitor;
measuring the capacitance of the reference capacitor;
providing an output relative to the proximity of the showerhead based upon the capacitance of the sensing and reference capacitances.

2. The method of claim 1, wherein the second sensing capacitance plate is operably supported by the substrate support pedestal.

3. The method of claim 1, wherein the at least one external factor includes temperature.

4. The method of claim 1, wherein the at least one external factor includes relative humidity.

5. The method of claim 1, wherein the at least one external factor includes a plurality of external factors.

6. The method of claim 1, wherein the output is calculated by a controller.

7. The method of claim 1, wherein measuring the capacitance of the reference capacitor occurs periodically.

8. The method of claim 1, and further comprising scaling the measured reference capacitance.

9. A method of sensing proximity to a showerhead in a semiconductor-processing system, the method comprising:
measuring a parameter that varies with proximity to the showerhead, as well as with at least one external factor;
measuring a parameter that does not vary with proximity to the showerhead, but does vary with the at least one factor;
calculating a compensated proximity output based upon the measured parameters; and
providing the calculated proximity output.

10. The method of claim 9, wherein the method is performed by a sensor resting upon a substrate support pedestal.

11. The method of claim 10, wherein the external factor includes at least one factor from the group consisting of temperature, relative humidity, and sensor age.

12. A sensor for sensing proximity to a showerhead in a semiconductor processing system, the sensor comprising:
a controller;
capacitance measurement circuitry operably coupled to the controller;
a proximity sensing capacitor operably coupled to the capacitance measurement circuitry;
a reference capacitor operably coupled to the capacitance measurement circuitry; and
wherein the controller is configured to provide a compensated proximity output based upon a sense capacitance and a reference capacitance.

13. The sensor of claim 12, wherein the proximity sensing capacitor is formed from a plurality of capacitive plates disposed on the sensor.

14. The sensor of claim 13, wherein the reference capacitor is formed of a plurality of capacitive plates disposed within the sensor on a circuit board of the sensor.

15. The sensor of claim 12, wherein the proximity sensing capacitor and the reference capacitor have the same nominal capacitance.

16. The sensor of claim 12, and further comprising switching circuitry operably coupled to the controller, the capacitance measurement circuitry, the proximity sensing capacitor and the reference capacitor.

17. The sensor of claim 12, and further comprising a temperature sensor operably coupled to the controller.
